(19) United States
(12) Patent Application Publication
(10) Pub. No.: US 2025/0323619 A1
(43) Pub. Date: Oct. 16, 2025

(54) HIGH-POWER ACOUSTIC WAVE FILTER PACKAGE CAPABLE OF SELF-HEAT DISSIPATION

(71) Applicant: Samsung Electronics Co., Ltd., Suwon-si (KR)

(72) Inventors: Dongjin JUNG, Suwon-si (KR); Jaekwang KWON, Suwon-si (KR); Kyeongho YEOM, Suwon-si (KR); Daeyoung LEE, Suwon-si (KR); Jiantong LI, Suwon-si (KR)

(21) Appl. No.: 19/084,128

(22) Filed: Mar. 19, 2025

Related U.S. Application Data
(60) Provisional application No. 63/632,686, filed on Apr. 11, 2024.

(51) Int. Cl. H03H 9/08; H03H 9/00; H03H 9/74

(52) U.S. Cl. CPC H03H 9/08; H03H 9/0004; H03H 9/74

(57) ABSTRACT

A filter package is provided. The filter package includes a plurality of metal layers stacked in a vertical direction, a plurality of acoustic wave filters connected in parallel, the plurality of acoustic wave filters being located at one of the plurality of metal layers, power dividing and combining components connected with the plurality of acoustic wave filters, and heat dissipating components.

### CROSS-REFERENCE TO RELATED APPLICATION(S)

This application is based on and claims priority under 35 U.S.C. § 119(e) of a U.S. Provisional application Ser. No. 63/632,686, filed on Apr. 11, 2024, in the U.S. Patent and Trade Office, the disclosure of which is incorporated by reference herein in its entirety.

### BACKGROUND

### 1. Field

The disclosure relates to a wireless communication system. More particularly, the disclosure relates to an acoustic wave filter for supporting high power in a wireless communication system and an electronic device including the same.

### 2. Description of Related Art

5^{th} generation (5G) mobile communication technologies define broad frequency bands such that high transmission rates and new services are possible, and can be implemented not only in “Sub 6 GHz” bands, such as 3.5 GHZ, but also in “Above 6 GHz” bands referred to as millimeter wave (mmWave) including 28 GHz and 39 GHZ. In addition, it has been considered to implement 6th generation (6G) mobile communication technologies (referred to as Beyond 5G systems) in terahertz bands (for example, 95 GHz to 3 THz bands) in order to accomplish transmission rates fifty times faster than 5G mobile communication technologies and ultra-low latencies one-tenth of 5G mobile communication technologies.

At the beginning of the development of 5G mobile communication technologies, in order to support services and to satisfy performance requirements in connection with enhanced mobile broadband (eMBB), ultra reliable low latency communications (URLLC), and massive machine-type communications (mMTC), there has been ongoing standardization regarding beamforming and massive multi input multi output (MIMO) for mitigating radio-wave path loss and increasing radio-wave transmission distances in mmWave, supporting numerologies (for example, operating multiple subcarrier spacings) for efficiently utilizing mmWave resources and dynamic operation of slot formats, initial access technologies for supporting multi-beam transmission and broadbands, definition and operation of bandwidth part (BWP), new channel coding methods, such as a low density parity check (LDPC) code for large amount of data transmission and a polar code for highly reliable transmission of control information, layer 2 (L2) pre-processing, and network slicing for providing a dedicated network specialized to a specific service.

Currently, there are ongoing discussions regarding improvement and performance enhancement of initial 5G mobile communication technologies in view of services to be supported by 5G mobile communication technologies, and there has been physical layer standardization regarding technologies, such as vehicle-to-everything (V2X) for aiding driving determination by autonomous vehicles based on information regarding positions and states of vehicles transmitted by the vehicles and for enhancing user convenience, new radio unlicensed (NR-U) aimed at system operations conforming to various regulation-related requirements in unlicensed bands, new radio (NR) user equipment (UE) power saving, non-terrestrial network (NTN) which is UE-satellite direct communication for providing coverage in an area in which communication with terrestrial networks is unavailable, and positioning.

Moreover, there has been ongoing standardization in air interface architecture/protocol regarding technologies, such as industrial Internet of things (IIoT) for supporting new services through interworking and convergence with other industries, integrated access and backhaul (IAB) for providing a node for network service area expansion by supporting a wireless backhaul link and an access link in an integrated manner, mobility enhancement including conditional handover and dual active protocol stack (DAPS) handover, and two-step random access for simplifying random access procedures (2-step random access channel (RACH) for NR). There also has been ongoing standardization in system architecture/service regarding a 5G baseline architecture (for example, service based architecture or service based interface) for combining network functions virtualization (NFV) and software-defined networking (SDN) technologies, and mobile edge computing (MEC) for receiving services based on UE positions.

As 5G mobile communication systems are commercialized, connected devices that have been exponentially increasing will be connected to communication networks, and it is accordingly expected that enhanced functions and performances of 5G mobile communication systems and integrated operations of connected devices will be necessary. To this end, new research is scheduled in connection with extended reality (XR) for efficiently supporting augmented reality (AR), virtual reality (VR), mixed reality (MR) and the like, 5G performance improvement and complexity reduction by utilizing artificial intelligence (AI) and machine learning (ML), AI service support, metaverse service support, and drone communication.

Furthermore, such development of 5G mobile communication systems will serve as a basis for developing not only new waveforms for providing coverage in terahertz bands of 6G mobile communication technologies, multi-antenna transmission technologies, such as full dimensional MIMO (FD-MIMO), array antennas and large-scale antennas, metamaterial-based lenses and antennas for improving coverage of terahertz band signals, high-dimensional space multiplexing technology using orbital angular momentum (OAM), and reconfigurable intelligent surface (RIS), but also full-duplex technology for increasing frequency efficiency of 6G mobile communication technologies and improving system networks, AI-based communication technology for implementing system optimization by utilizing satellites and AI from the design stage and internalizing end-to-end AI support functions, and next-generation distributed computing technology for implementing services at levels of complexity exceeding the limit of UE operation capability by utilizing ultra-high-performance communication and computing resources.

Further, the number of components included in a communication device necessarily increases to support multi-antenna transmission technologies, such as FD-MIMO, an array antenna, and a large-scale antenna.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a filter (or filter package) for supporting high power in a wireless communication system and a device including the same.

Another aspect of the disclosure is to provide a filter (or filter package) capable of self-heat dissipation in a wireless communication system and a device including the same.

Additional aspects will be set forth in part in the description which follows and, in part, will be apparent from the description, or may be learned by practice of the presented embodiments.

In accordance with an aspect of the disclosure, a filter package is provided. The filter package includes a plurality of metal layers stacked in a vertical direction, a plurality of acoustic wave filters connected in in parallel, the plurality of acoustic wave filters being located at one of the plurality of metal layers, power dividing and combining components connected with the plurality of acoustic wave filters, and heat dissipating components.

In accordance with another aspect of the disclosure, an electric device in a wireless communication system is provided. The electric device includes antennas and a filter device operably connected to at least one of the antennas, where the filter device includes a plurality of acoustic wave filters connected in parallel, power dividing and combining components connected with the plurality of acoustic wave filters, and heat dissipating components.

According to an embodiment of the disclosure, it is possible to achieve performance similar to that of a high-power filter by using low-power filters (e.g., an acoustic wave filter die).

Further, according to an embodiment of the disclosure, heat generation that autonomously occurs in a filter is resolved by inserting a heat dissipating structure into a filter package, thereby solving deterioration in performance, such as passband drift due to temperature.

In addition, according to an embodiment of the disclosure, a filter package is miniaturized compared to a high-power filter, such as metallic/ceramic cavity waveguide filters of the related art, and has a great advantage in production costs. Therefore, it is possible to contribute to miniaturization of a communication device and reduction in production costs thereof.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a wireless network according to an embodiment of the disclosure;

FIG. 2 illustrates a front-end module (FEM) of a radio frequency (RF) termination according to an embodiment of the disclosure;

FIG. 3A illustrates a metallic cavity filter according to an embodiment of the disclosure;

FIG. 3B illustrates a ceramic cavity filter according to an embodiment of the disclosure;

FIG. 4 illustrates a 3.5-GHz massive MIMO unit (MMU) according to an embodiment of the disclosure;

FIG. 5 illustrates a one RF/antenna board type for miniaturizing an MMU and a base station device according to an embodiment of the disclosure;

FIGS. 6A and 6B illustrate a power splitting concept according to an embodiment of the disclosure;

FIG. 7 illustrates a bulk acoustic wave (BAW filter) package according to the related art;

FIG. 8 illustrates a high-power acoustic wave filter package according to an embodiment of the disclosure;

FIG. 9 illustrates why an additional impedance matching circuit is required according to an embodiment of the disclosure;

FIG. 10A illustrates a top-view of a high-power acoustic wave filter package according to an embodiment of the disclosure;

FIG. 10B illustrates cross-sectional views of a high-power acoustic wave filter package according to an embodiment of the disclosure;

FIG. 11 illustrates a method for connecting thermal bonding wires according to an embodiment of the disclosure;

FIG. 12 illustrates adding a heat sink to a high-power acoustic wave filter package according to an embodiment of the disclosure;

FIG. 13 illustrates a designed high-power acoustic wave filter package according to an embodiment of the disclosure;

FIG. 14 illustrates a result of a large-signal simulation of a high-power acoustic wave filter package according to an embodiment of the disclosure;

FIG. 15A illustrates a result of a small-signal simulation of a high-power acoustic wave filter package according to an embodiment of the disclosure;

FIG. 15B illustrates a result of a small-signal simulation of a high-power acoustic wave filter package according to an embodiment of the disclosure;

FIG. 16A illustrates high-power acoustic wave filter packages designed to verify an effect of thermal bonding wires according to an embodiment of the disclosure;

FIG. 16B illustrates a thermal analysis result according to whether a thermal bonding wire is applied according to an embodiment of the disclosure;

FIG. 17 illustrates a high-power acoustic wave filter package designed using a Wilkinson divider according to an embodiment of the disclosure;

FIG. 18 illustrates a high-power acoustic wave filter package designed using a 180-degree hybrid coupler according to an embodiment of the disclosure;

FIGS. 19A and 19B illustrate a high-power acoustic wave filter package according to an embodiment of the disclosure;

FIGS. 20A, 20B, and 20C illustrate a high-power acoustic wave filter package structure according to an embodiment of the disclosure;

FIG. 21 illustrates a high-power acoustic wave filter package according to an embodiment of the disclosure;

FIG. 22 illustrates a high-power acoustic wave filter package according to an embodiment of the disclosure; and

FIG. 23 illustrates an electronic device according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

For the same reason, in the accompanying drawings, some elements may be exaggerated, omitted, or schematically illustrated. Further, the size of each element does not completely reflect the actual size. In the drawings, identical or corresponding elements are provided with identical reference numerals.

The advantages and features of the disclosure and ways to achieve them will be apparent by making reference to embodiments as described below in conjunction with the accompanying drawings. However, the disclosure is not limited to the embodiments set forth below, but may be implemented in various different forms. The following embodiments are provided only to completely disclose the disclosure and inform those skilled in the art of the scope of the disclosure, and the disclosure is defined only by the scope of the appended claims. Throughout the specification, the same or like reference numerals designate the same or like elements. Further, in describing the disclosure, a detailed description of known functions or configurations incorporated herein will be omitted when it is determined that the description may make the subject matter of the disclosure unnecessarily unclear. The terms which will be described below are terms defined based on the functions in the disclosure, and may be different according to users, intentions of the users, or customs. Therefore, the definitions of the terms should be made based on the contents throughout the specification.

Herein, it will be understood that each block of the flowchart illustrations, and combinations of blocks in the flowchart illustrations, can be implemented by computer program instructions. These computer program instructions can be provided to a processor of a general-purpose computer, special purpose computer, or other programmable data processing apparatus to produce a machine, such that the instructions, which execute via the processor of the computer or other programmable data processing apparatus, create means for implementing the functions specified in the flowchart block or blocks. These computer program instructions may also be stored in a computer usable or computer-readable memory that can direct a computer or other programmable data processing apparatus to function in a particular manner, such that the instructions stored in the computer usable or computer-readable memory produce an article of manufacture including instruction means that implement the function specified in the flowchart block or blocks.

The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart block or blocks.

Further, each block of the flowchart illustrations may represent a module, segment, or portion of code, which includes one or more executable instructions for implementing the specified logical function(s). It should also be noted that in some alternative implementations, the functions noted in the blocks may occur out of the order. For example, two blocks shown in succession may in fact be executed substantially concurrently or the blocks may sometimes be executed in the reverse order, depending upon the functionality involved.

As used herein, the “unit” refers to a software element or a hardware element, such as a field programmable gate array (FPGA) or an application specific integrated circuit (ASIC), which performs a predetermined function. However, the “unit” does not always have a meaning limited to software or hardware. The “unit” may be constructed either to be stored in an addressable storage medium or to execute one or more processors. Therefore, the “unit” includes, for example, software elements, object-oriented software elements, class elements or task elements, processes, functions, properties, procedures, sub-routines, segments of a program code, drivers, firmware, micro-codes, circuits, data, database, data structures, tables, arrays, and parameters. The elements and functions provided by the “unit” may be either combined into a smaller number of elements, or a “unit”, or divided into a larger number of elements, or a “unit”. Moreover, the elements and “units” or may be implemented to reproduce one or more CPUs within a device or a security multimedia card. Further, the “unit” in the embodiments may include one or more processors.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

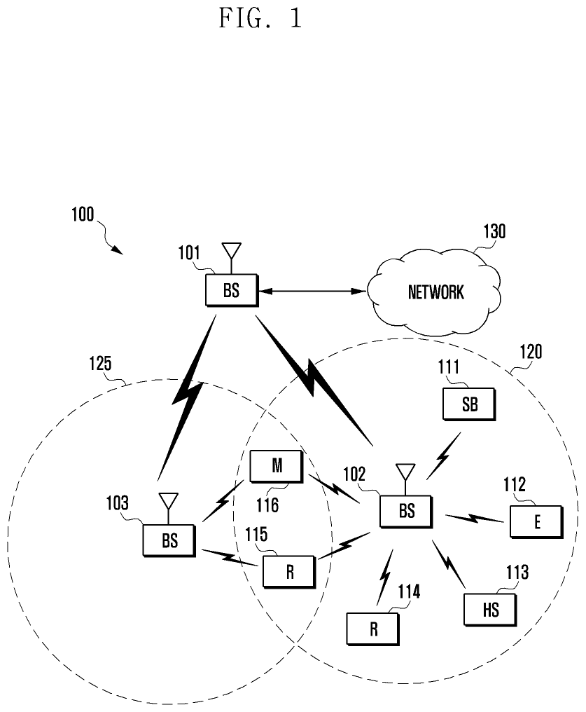

FIG. 1 illustrates a wireless network according to an embodiment of the disclosure.

The example of the wireless network illustrated in FIG. 1 is only for illustration. Other embodiments of wireless networks may be used without departing from the scope of the disclosure.

Referring to FIG. 1, a wireless network 100 may include a base station (BS) 101, a BS 102, and a BS 103. The BS 101 communicates with the BS 102 and the BS 103. The BS 101 also communicates with at least one network 130, such as the Internet, a proprietary Internet protocol (IP) network, or another data network.

The BS 102 may provide wireless broadband access to the network 130 for a plurality of first user equipments (UEs) within a coverage area 120 of the BS 102. The plurality of first UEs may include a UE 111 locatable in a small company, a UE 112 locatable in an enterprise (E), a UE 113 locatable in a Wi-Fi hotspot (HS), a UE 114 locatable in a first residence (R), a UE 115 locatable in a second residence (R), and a UE 116 that may be a mobile device (M), such as a cellular phone, a wireless laptop computer, and a wireless PDA. The BS 103 provides wireless broadband access to the network 130 for a plurality of second UEs within a coverage area 125 of BS 103. The plurality of second UEs include the UE 115 and the UE 116. In some embodiments of the disclosure, one or more of the BSs 101 and 103 may communicate with each other, and may also communicate with the UEs 111 to 116 by using 5G, LTE, LTE-A, WiMAX, Wi-Fi, or other wireless communication technologies.

Depending on network types, the term “base station (BS)” may refer to any component (or set of components) configured to provide wireless access to a network, such as a transmission point (TP), a transmit-receive point (TRP), an enhanced base station (eNodeB or eNB), a 5G base station (gNB), a macrocell, a femtocell, a Wi-Fi access point (AP), or other wirelessly enabled devices. A base station may provide wireless access according to one or more wireless communication protocols, such as 5G 3GPP new radio interface/access (NR), long-term evolution (LTE), LTE advanced (LTE-A), high-speed packet access (HSPA), and Wi-Fi 802.11a/b/g/n/ac. For convenience, the terms “BS” and “TRP” may be interchangeably used in the disclosure to refer to a network infrastructure component that provides wireless access for a remote UE.

Further, depending on network types, the term “user equipment (UE)” may be referred to as a mobile station, a subscriber station (SS), a terminal, a remote terminal, a wireless terminal, a receiving point, a mobile equipment (ME), a user terminal (UT), a wireless device, an access terminal (AT), a handheld device, an access terminal (AT), a wireless communication device, a wireless transmit/receive unit (WTRU), a mobile node, a mobile, or other terms. For convenience, the terms “user equipment” and “UE” in the disclosure are used to refer to a remote wireless device that wirelessly connects to a BS, and a UE may be a mobile phone, a cellular telephone, a personal digital assistant (PDA), a smartphone having a wireless communication function, a wireless MODEM, a laptop computer, an earbud, a portable computer having a wireless communication function, a photographing device, such as a digital camera having a wireless communication function, a gaming device having a wireless communication function, a music storage and playback home appliance having a wireless communication function, a home appliance having a wireless communication function, an internet home appliances capable of wireless internet access and browsing, and portable units or terminals in which combinations of the above functions are integrated.

Dotted lines indicate the approximate extents of the coverage areas 120 and 125, which are depicted as approximate circles only for illustration and explanation. It should be clearly understood that a coverage area associated with a BS, such as the coverage areas 120 and 125, may have different shapes, including an irregular shape, depending on the configuration of the BS and changes in a wireless environment associated with natural and artificial obstacles.

Although FIG. 1 shows an example of a wireless network, various modifications may be made to FIG. 1. For example, the wireless network may include any number of BSs and any number of UEs in any suitable arrangement. In addition, the BS 101 may communicate directly with any number of UEs, and may provide the UEs with wireless broadband access to the network 130. Similarly, each of the BSs 102 and 103 may communicate directly with the network 130, and may provide the UEs with direct wireless broadband access to the network 130. Further, the BSs 101, 102, and/or 103 may provide access to other or additional external networks, such as an external telephone network or other types of data network.

Hereinafter, in the disclosure, the BSs 101, 102, and 103 or the UEs 111, 112, 113, 114, and 115 of FIG. 1 may be referred to as an electronic device. To explain embodiments of the disclosure, an example in which the electronic device is a base station (BS) is illustrated, but various embodiments of the disclosure are not limited thereto. As an electronic device, a wireless device performing a function equivalent to that of a base station, a wireless device (e.g., a TRP) connected to a base station, a terminal, or any other communication device used for wireless communication may be possible in addition to a base station. In the disclosure, the electronic device may be simply expressed as a device.

The electronic device may include a front-end module (FEM) to transmit or receive a signal on various frequencies.

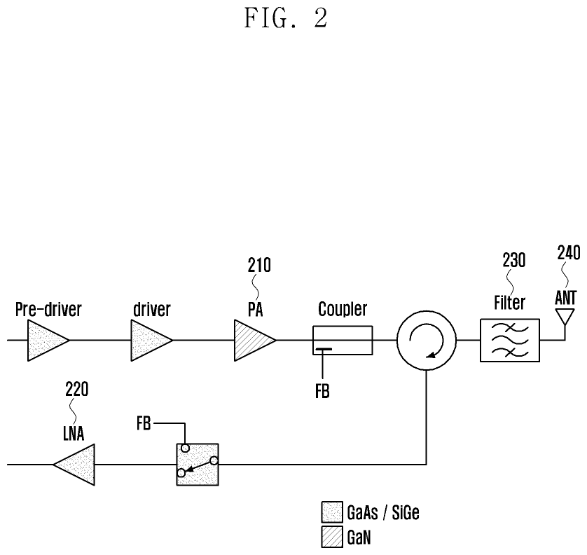

FIG. 2 illustrates an FEM of a radio frequency (RF) termination according to an embodiment of the disclosure.

Referring to FIG. 2, an electronic device of a wireless communication system may include a power amplifier (PA) 210, a low-noise amplifier (LNA) 220, a filter 230, and an antenna 240. The filter may refer to a circuit that performs filtering by forming resonance so that a signal of a desired frequency is transmitted. For example, the filter may perform a function of selectively identifying a frequency. In the electronic device, the PA 210 may be disposed on a transmitting (Tx) path to transmit a signal, and the LNA 220 may be disposed on a receiving (Rx) path to amplify a received signal. The filter 230 may be disposed at the antenna 240 to increase the frequency selectivity of a signal having a specific frequency on the Tx path and the Rx path.

More particularly, a high-power signal is output from the PA on the Tx path for long-distance transmission of the signal, and the filter requires high power handling capability to handle high power. In addition, the temperature of the filter rises high due to heat generated by the loss of the filter, and thus a filter technology allowing low passband drift of the filter according to temperature is important.

To satisfy high power handling capability and low passband drift according to temperature, waveguide-type cavity filters using a metallic or ceramic cavity have been used for a base station.

A cavity filter is a type of RF filter that operates according to the principle of resonance. Physically, the cavity filter includes a resonator with a “tuning screw” (finely adjusting the frequency) in a “conducting box.” In the cavity filter, the resonator is mounted with a screw for adjusting a frequency range, and a resonance frequency may be adjusted by modifying the physical length of the resonator (length of an internal space) and capacitance with respect to a ground. When an RF signal passes through the cavity filter, the resonator serves as a bandpass filter, and passes the RF signal at a specific frequency (i.e., the resonance frequency) while blocking other nearby frequencies.

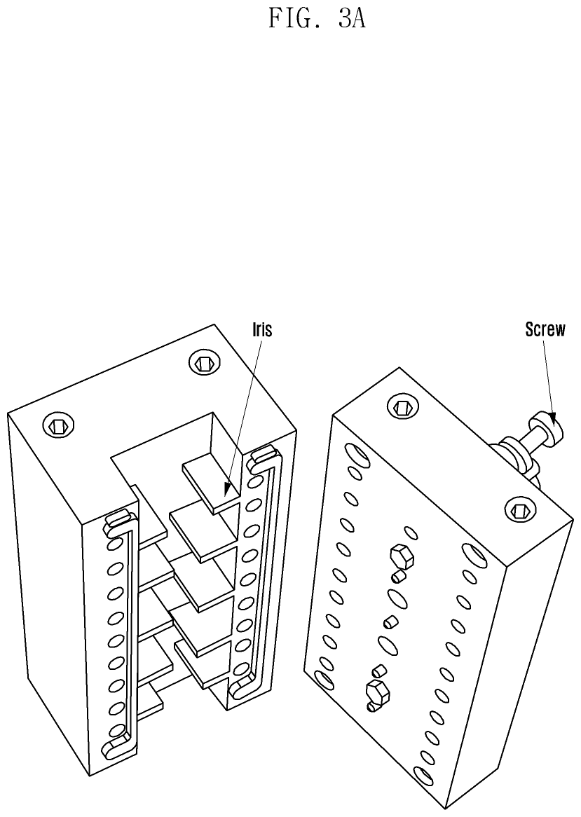

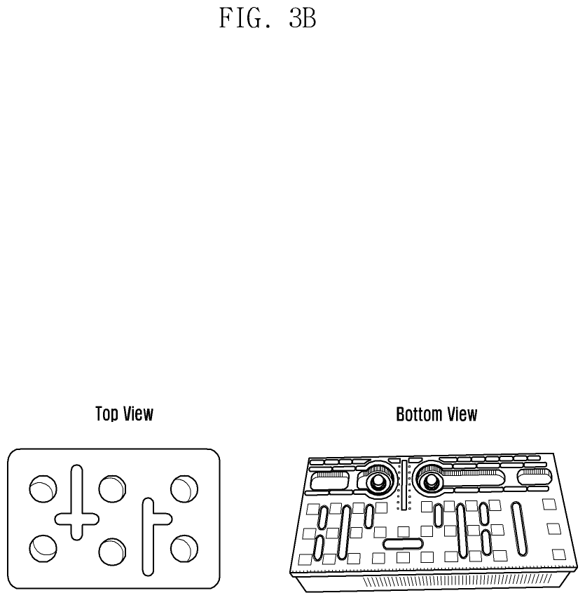

FIG. 3A illustrates a metallic cavity filter according to an embodiment of the disclosure.

Referring to FIG. 3A, filters using a metallic waveguide cavity shape have been used as bandpass filters for a base station of the related art. Metallic cavity filters are large and heavy, making it difficult to miniaturize a base station.

FIG. 3B illustrates a ceramic cavity filter according to an embodiment of the disclosure.

Referring to FIG. 3B, the ceramic cavity filter is lighter than the metallic cavity filter of FIG. 3A, but the size of the ceramic cavity filter also makes it difficult to miniaturize a base station.

However, when designing a base station for a post-5G (e.g., 6G) communication system using a next-generation massive-MIMO technology, the number of RF Tx/Rx paths significantly increases. When a filter is inserted into each of an increased number of RF paths, the increased number of filters makes it difficult to miniaturize the base station and to reduce costs for implementing the base station.

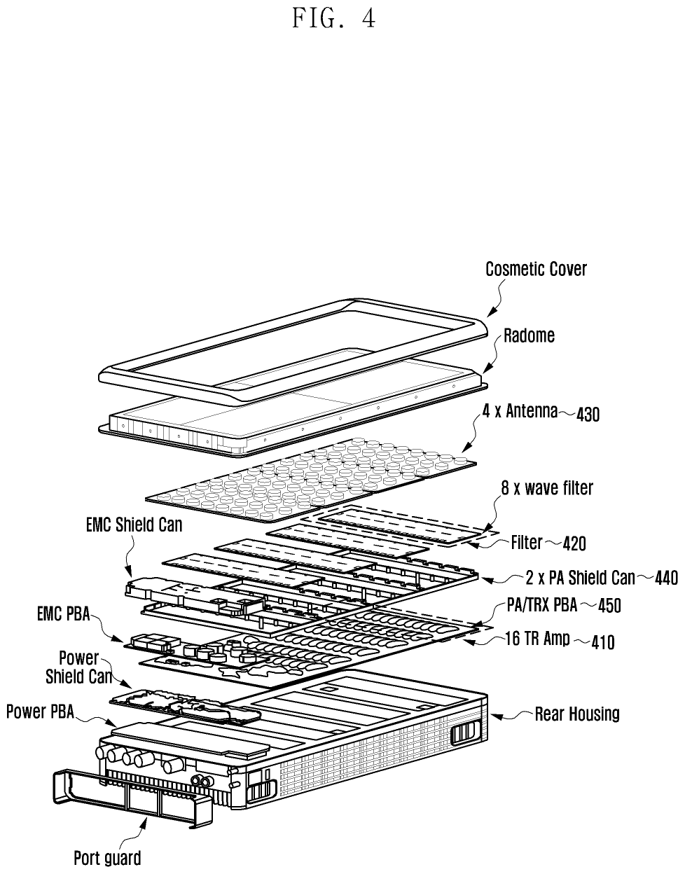

FIG. 4 illustrates a 3.5-GHz massive MIMO unit (MMU) according to an embodiment of the disclosure.

Referring to FIG. 4, a base station may include an MMU. Elements of a filter part 420 correspond to ceramic cavity filters in the 3.5-GHz MMU. A total of 64 ceramic cavity filters are mounted in a surface-mount form on a printed circuit board (PCB), and an independent separate PCB is required for such mounting.

A metal shield can 440 is added for isolation between an antenna PCB 430 and a PA/TRX board 450. The PA/TRX board refers to a PCB on which a power amplifier (PA) and RF circuits 410 are mounted. The existing 3.5-GHz MMU is used with a structure in which a plurality of separate PCBs for an antenna, the filters, and the RF circuits are stacked, which increases the size of the MMU.

In addition, when a ceramic cavity filter or a metallic cavity filter is used for designing the MMU, a separate PCB for mounting the filter is required, which increases the size, weight, and production cost of the MMU.

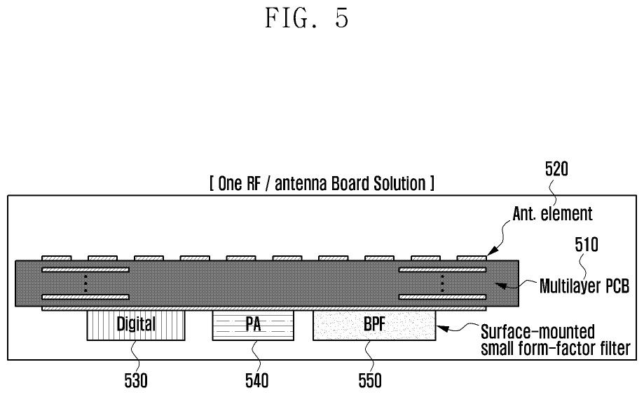

FIG. 5 illustrates a one RF/antenna board type for miniaturizing an MMU and a base station device according to an embodiment of the disclosure.

Referring to FIG. 5, in a one RF/antenna board solution, not only an RF circuit including an antenna array (or antenna element) 520 and a PA 540 but also digital circuits 530 may be mounted on a single PCB 510 including a plurality of layers, and a bandpass filter (BPF) 550 may also be mounted thereon.

A highly integrated circuit structure in which circuits for various purposes are mounted on a single PCB makes it possible to miniaturize an MMU and a base station device. However, when a metallic cavity filter or ceramic cavity filter technology of the related art is used as a BPF, a one RF/antenna board solution is impossible due to the volume of the filter.

Therefore, a technology for a miniaturized filter that enables a one RF/antenna board solution is required. An acoustic wave filter may be taken into consideration as a technology enabling a miniaturized filter that has a high quality factor of a resonator, provides high frequency selectivity, and is capable of being surface-mounted on a PCB. Acoustic wave filters include a surface acoustic wave (SAW) filter using a surface acoustic wave (SAW) and a bulk acoustic wave (BAW) filter using a bulk acoustic wave (BAW).

Both the SAW filter and the BAW filter operate by converting electrical energy into acoustic or mechanical energy in piezoelectric materials. Major differences between the two filters are physical structures and methods of propagating acoustic waves. While acoustic waves travel along the surface of a piezoelectric substrate in the SAW filter, acoustic waves propagate vertically through the bulk of a piezoelectric substrate material in the BAW filter. The SAW filter supports a frequency of up to 3 GHz, is sensitive to temperature, and has low power handling capability. However, the BAW filter is able to operate at a higher frequency (e.g., 10 GHZ), is less sensitive to temperature changes, and has higher power handling capability than the SAW filter.

Acoustic wave filters, such as the SAW filter and BAW filter of the related art, have a power handling capability to support approximately 1 Watt (W) or less, and have a passband drift problem due to temperature. Thus, acoustic wave filters are not available for a base station and an MMU device.

Therefore, an acoustic wave filter (e.g., a SAW filter and a BAW filter) capable of operating at a high power of 1 W or more essentially needs to be developed for miniaturization of a base station and an MMU device.

In addition, a heat dissipating structure needs to be inserted to minimize deterioration in the performance of the filters due to heat generated when the SAW filter and the BAW filter operate at high power.

The disclosure proposes a self-heat dissipating high-power acoustic wave filter package that has high power handling capability while minimizing passband drift due to temperature.

In the disclosure, a filter package may be referred to as a filter module. In addition, a filter package may be referred to simply as a package in the disclosure. Although the disclosure illustrates a BAW filter as an example of an acoustic wave Filter, the scope of the disclosure is not limited thereto. Therefore, not only the BAW filter but also a SAW filter and other low-power filters may be used as an acoustic wave filter. In the disclosure, filters, such as the SAW filter and the BAW filter may be referred to as low-power filters.

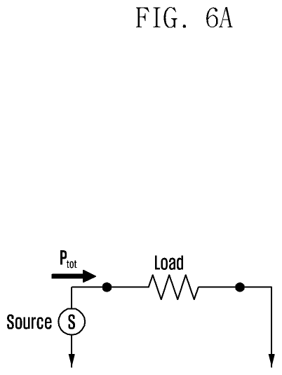

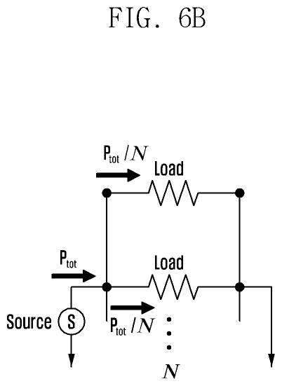

FIGS. 6A and 6B illustrate a power splitting concept according to an embodiment of the disclosure.

Referring to FIG. 6A, since one load is connected to a source, power applied to the load is equal to power Pₜₒₜ generated from the source. However, referring to FIG. 6B, since N (e.g., N is an integer of 2 or greater) loads are connected in parallel, a power of Pₜₒₜ/N, which is smaller than power Pₜₒₜ generated from a source, is applied to each load. The concept illustrated in FIG. 6B may be used for designing a filter package using an acoustic wave filter.

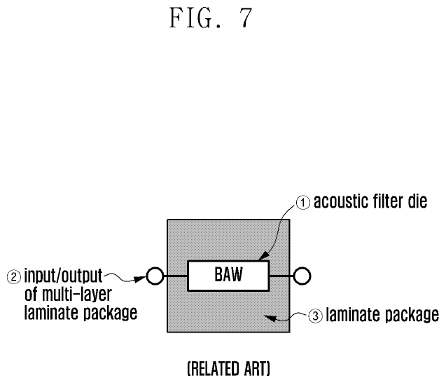

FIG. 7 illustrates a BAW filter package according to the related art.

FIG. 7 illustrates a BAW filter package of the related art, and the package may include one acoustic wave filter die. The BAW filter package of FIG. 7 may correspond to the concept of FIG. 6A.

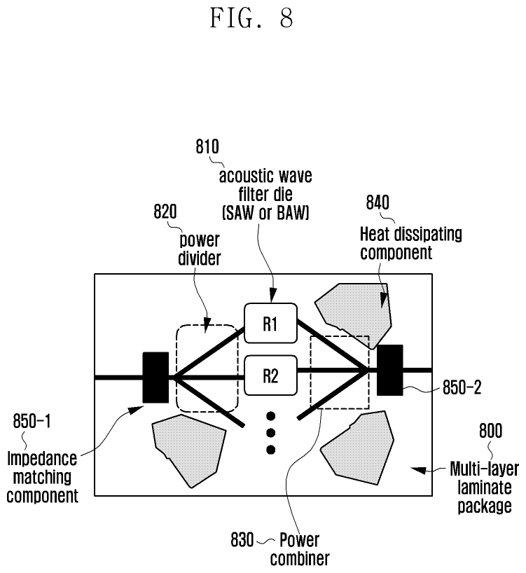

FIG. 8 illustrates a high-power acoustic wave filter package according to an embodiment of the disclosure.

Referring to FIG. 8, one package 800 may include a plurality of acoustic wave filter dies 810, a power divider (i.e., a power dividing component) 820, a power combiner (i.e., a power combining component) 830, a heat dissipating component 840, and an impedance matching circuit 850-1 and 850-2. The plurality of acoustic wave filter dies 810 in the one package may be connected in parallel. The acoustic wave filter dies refer to a component obtained from a wafer through dicing in a semiconductor process, i.e., a component not packaged. For example, the acoustic wave filter dies may be a SAW filter or a BAW filter. To connect the plurality of acoustic wave filter dies, the N-way power divider 820 may be connected to an input side of the acoustic wave filters, and the N-way power combiner 830 may be connected to an output side of the acoustic wave filters. Further, to improve a change in impedance matching due to a parallel connection of the filters, the additional impedance matching circuits 850-1 and 850-2 may be connected to an input side of the N-way power divider 820 and an output side of the N-way power combiner 830, respectively. The impedance matching circuit 850-1 connected to the N-way power divider 820 may be configured such that input impedance and load impedance are matched at an input terminal of the filter package. The load impedance may mean the sum of impedances of the plurality of filters 810 and the impedance matching circuit 850-1. The impedance matching circuit 850-2 connected to the N-way power combiner 830 may be configured such that the impedance from an output terminal of the filter package and load impedance are matched. The load impedance may mean the sum of impedances of the plurality of filters 810 and the impedance matching circuit 850-2. In addition, a heat dissipating component 840 may be inserted in the package to dissipate heat from the package. For example, the package may be manufactured using a multi-layer laminating package technology.

The operation of the high-power acoustic wave filter package illustrated in FIG. 8 is the same as that shown in FIG. 6B. A signal applied to the input of the package passes through the impedance matching component 850-1, and is divided by 1/N in the N-way power dividing circuit 820. Therefore, power applied to each acoustic wave filter die is lower than total power applied to the input, which may enable the operation of the acoustic wave filter even at high power.

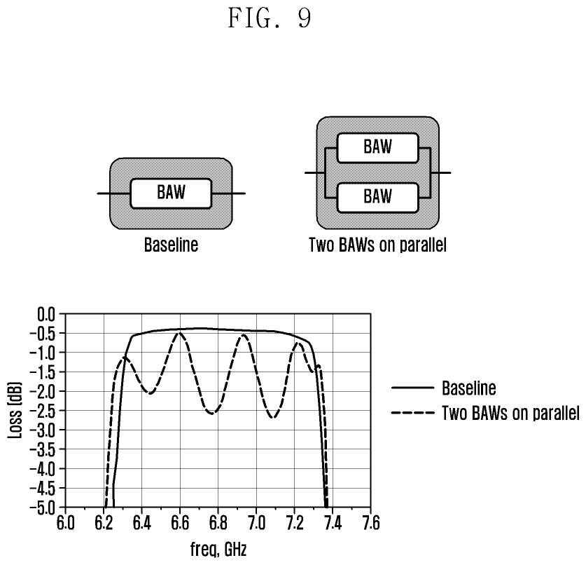

FIG. 9 illustrates why an additional impedance matching circuit is required according to an embodiment of the disclosure.

Referring to FIG. 9, “Baseline” is the result of a stand-alone BAW filter including one BAW filter, and “Two BAWs on Parallel” is the result of a filter package having a structure in which two identical BAW filters are connected in parallel. As shown in comparison between the simulation results, in the parallel connection of the two identical filters, when the plurality of filters disposed in parallel is directly connected to the input and output, a significant ripple occurs in a passband due to an impedance mismatch. The impedance mismatch that occurs when the identical filters are connected in parallel causes inefficiency in power transmission. Thus, to resolve the inefficiency, an additional impedance matching circuit may be connected to each of the input and output terminals.

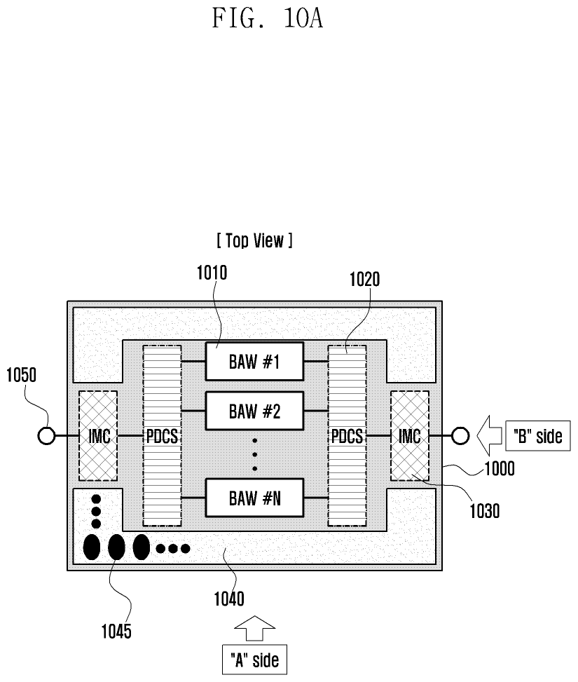

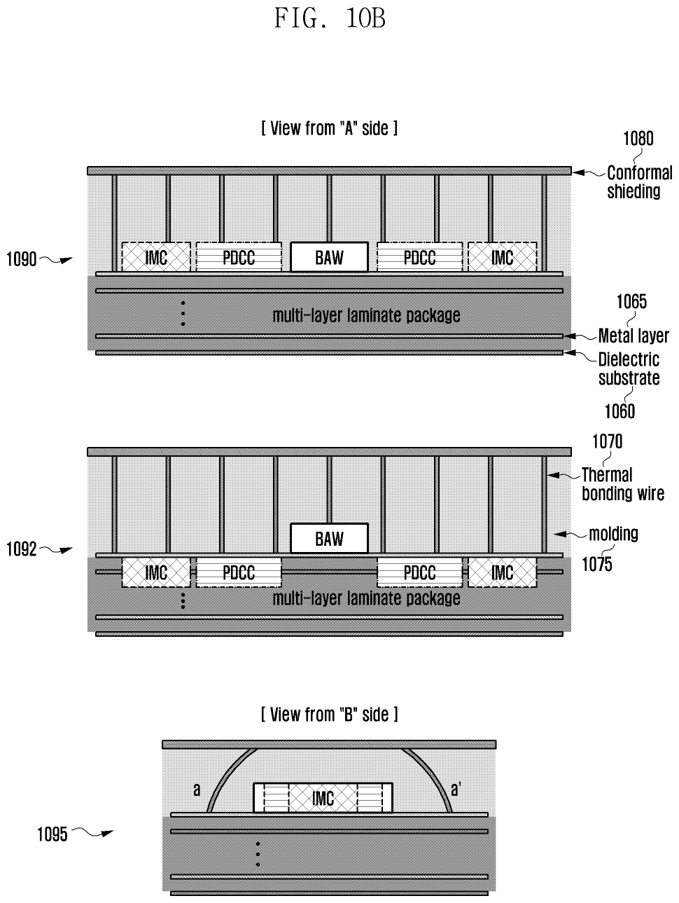

FIG. 10A illustrates a high-power acoustic wave filter package according to an embodiment of the disclosure.

FIG. 10B illustrates a high-power acoustic wave filter package according to an embodiment of the disclosure.

FIGS. 10A and 10B illustrate a implementation method and implementation form of the structure proposed in FIG. 8.

FIG. 10A illustrates a top view of a high-power acoustic wave filter package according to an embodiment of the disclosure.

Referring to FIG. 10A, acoustic wave filter dies 1010, a power dividing and combining structure (PDCS) 1020, an impedance matching circuit (IMC) 1030, and a grounded heat dissipating plane 1040 may be included in a single package 1000. For example, the package may be manufactured using a multi-layer laminating technique.

The acoustic wave filter dies 1010 may be disposed/connected in parallel. For example, the acoustic wave filter dies may be a SAW filter or a BAW filter. However, the scope of the disclosure is not limited thereto, and other low-power filters may be used.

The PDCS 1020 may be connected to each of the input and output of the acoustic wave filter dies 1010. The PDCS 1020 connected to the input of the acoustic wave filter dies 1010 may serve as a power divider, and the PDCS 1020 connected to the output of the acoustic wave filter dies 1010 may serve as a power combiner. The PDCS 1020 may have various structures. For example, the PDCS may be any circuit having a combination of a lumped inductor and a lumped capacitor. Alternatively, the PDCS may be fabricated on an integrated passive device (IPD).

The IMC 1030 may have various structures. For example, the IMC may be a combination of metal strips or open/short stubs of various shapes. Alternatively, the IMC may be configured using lumped inductors (L) and/or capacitors (C). Alternatively, the IMC may be configured using an IPD. A first IMC may be disposed on a path between the input of the package 1050 and the input of the PDCS. A second IMC may be disposed on a path between the output of the PDCS and the output of the package.

For example, the foregoing components may be disposed on the upper surface of a top metal layer of the package. Alternatively, the components may be disposed inside the package (i.e., an inner metal layer). Alternatively, when using a double-side ball grid array (DS-BGA) package, the components may be also disposed on the bottom surface of the package.

The grounded heat dissipating plane 1040 for heat dissipation may be formed in various metal shapes on the top metal layer of the package. Here, to maximize heat dissipation, the grounded heat dissipating plane disposed in the top metal layer may be connected to metal layers in other layers through vias. In addition, thermal bonding wires 1045 may be connected to the grounded heat dissipating plane to further improve heat dissipation. Accordingly, bonding pads for the thermal bonding wires may be disposed on the surface of the grounded heat dissipating plane.

FIG. 10B illustrates cross-sectional views of a high-power acoustic wave filter package according to an embodiment of the disclosure.

FIG. 10B shows cross-sectional views of the package illustrated in FIG. 10A.

Referring to FIG. 10B, 1090 and 1092 show cross-sectional views when viewed from a direction of side-A of FIG. 10A. Thermal bonding wires 1070 are disposed vertically on a grounded heat dissipating plane disposed in a top metal layer 1065 and a bottom dielectric substrate layer 1060 of a multi-layer laminate package. The thermal bonding wires 1070 may be connected to a conformal shielding 1080 existing on the top surface of a package mold layer 1075. The conformal shielding 1080 is for reducing the electromagnetic interference (EMI) of the package by coating the surface of the package with a thin metal layer, and may be laminated using a metal sputtering method.

In FIG. 10B, 1095 shows a cross-sectional view when viewed from a direction of side-B of FIG. 10A. Referring to the cross-sectional view from side-B, when the thermal bonding wires are connected, symmetrical points a and a′ may be connected with the thermal bonding wires.

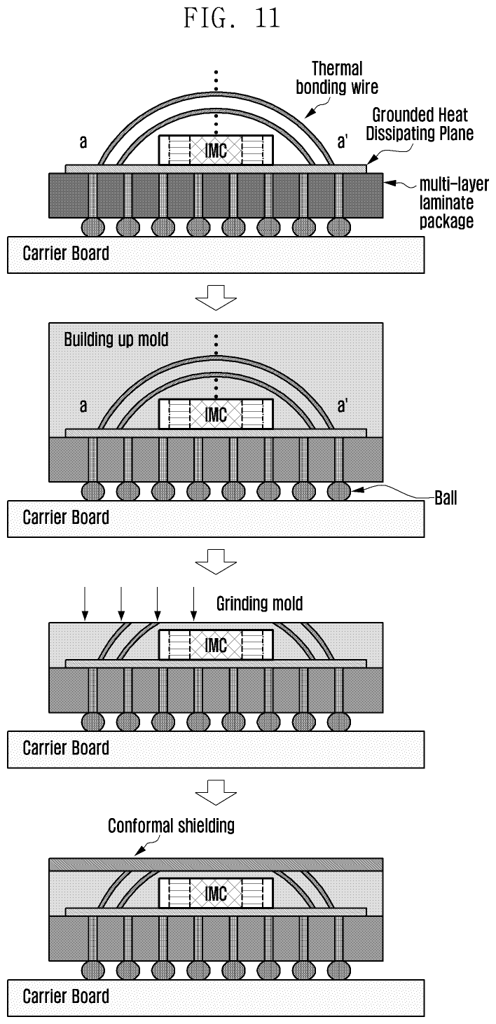

FIG. 11 illustrates a method for connecting thermal bonding wires according to an embodiment of the disclosure.

Referring to FIG. 11, thermal bonding pads to which thermal bonding wires are connected are assumed to exist on a grounded heat dissipating plane disposed in a top metal layer of a package. The thermal bonding wires may connect the thermal bonding pads at points (e.g., a and a′) that are vertically or horizontally symmetrical to each other with respect to the central axis of the package in a horizontal or vertical direction. For example, thick bonding wires may be used as the thermal bonding wires. Subsequently, a molding layer may be formed. The formed molding layer may be ground considering a height standard of the package. Next, a conformal shielding may be formed on the grinded molding layer. The connected thermal bonding wire array may form an electrical connection between the grounded heat dissipating plane and the conformal shielding.

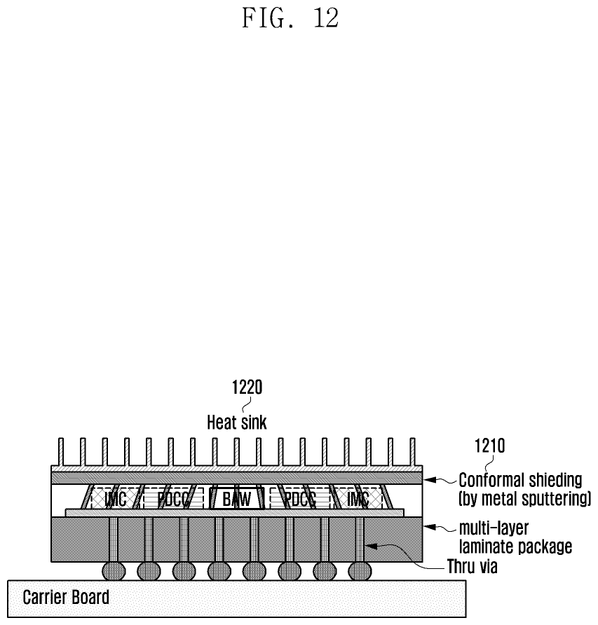

FIG. 12 illustrates adding a heat sink to a high-power acoustic wave filter package according to an embodiment of the disclosure.

Referring to FIG. 12, a heat sink 1220 may be added on the top of a conformal shielding 1210 generated after applying the thermal bonding wires illustrated in FIG. 11. When the additional heat sink is mounted, heat dissipation of the package may be maximized.

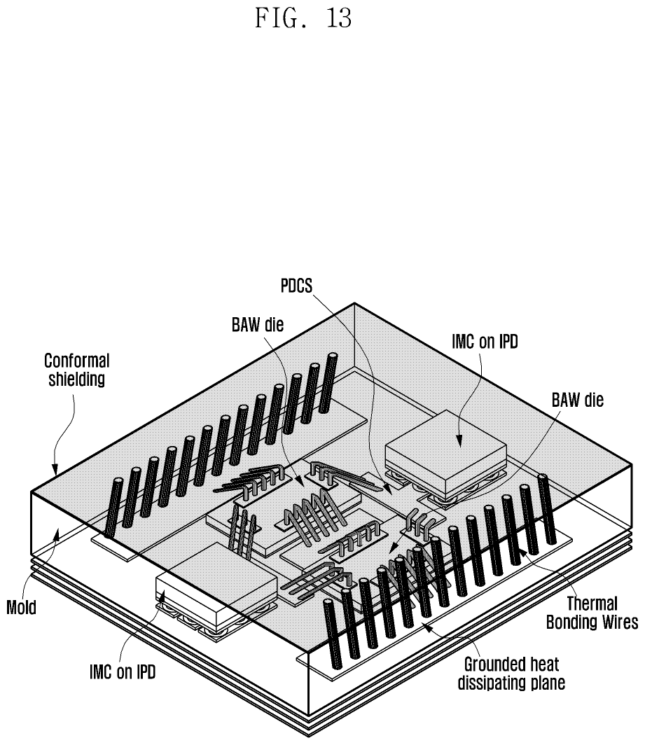

FIG. 13 illustrates a designed high-power acoustic wave filter package according to an embodiment of the disclosure.

Referring to FIG. 13, the filter package may be designed based on the foregoing method. Although the example of FIG. 13 shows that the package includes two acoustic wave filter dies for convenience of explanation, the package may include three or more acoustic wave filter dies.

Referring to FIG. 13, an IMC may be configured using an integrated passive device (IPD) using a silicon wafer process. A PDCS may apply a signal to two acoustic wave filters through a boding wire. BAW filters are used as the acoustic wave filters in the example of FIG. 13, but other filters may be applied.

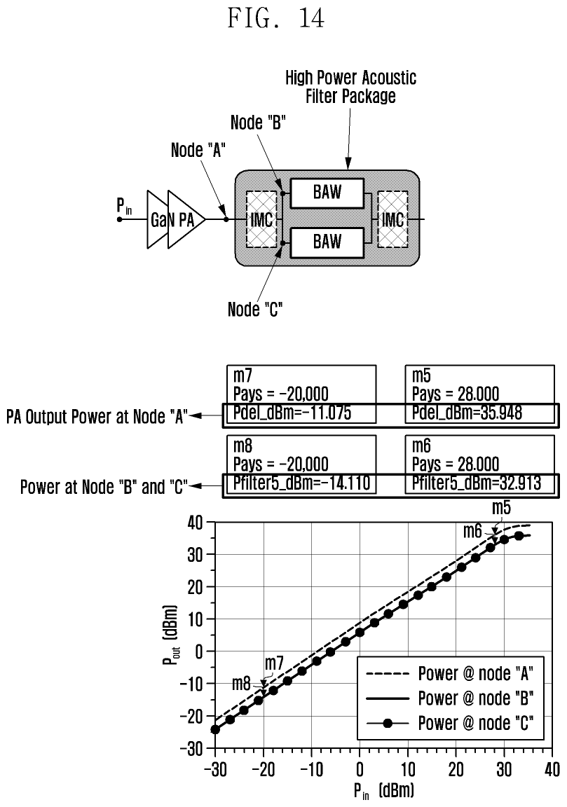

FIG. 14 illustrates a result of a large-signal simulation of a high-power acoustic wave filter package according to an embodiment of the disclosure.

Referring to FIG. 14, input powers to a BAW filter measured at Node B and Node C are identified as being reduced exactly by ½ compared to PA output power at Node A.

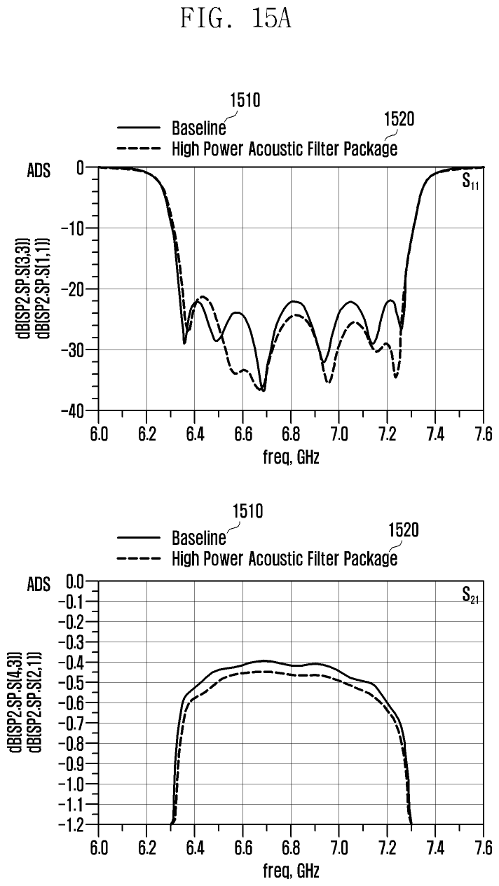

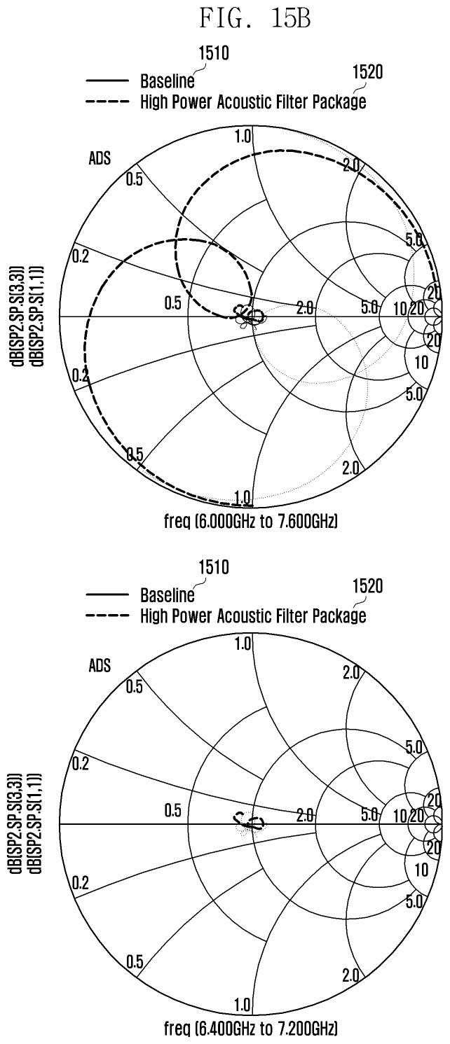

FIGS. 15A and 15B illustrate a result of a small-signal simulation of a high-power acoustic wave filter package according to an embodiment of the disclosure.

FIGS. 15A and 15B show a result of a simulation using a model illustrated in FIG. 13.

Referring to FIGS. 15A and 15B, line 1510 representing a baseline shows performance when one BAW filter is connected, and line 1520 shows the performance of a high-power acoustic wave filter package designed according to an embodiment of the disclosure. As illustrated in FIGS. 15A and 15B, the proposed design has an increase in loss by 0.1 dB or less compared to the existing filter, but overall frequency response characteristics of the filter may be maintained the same.

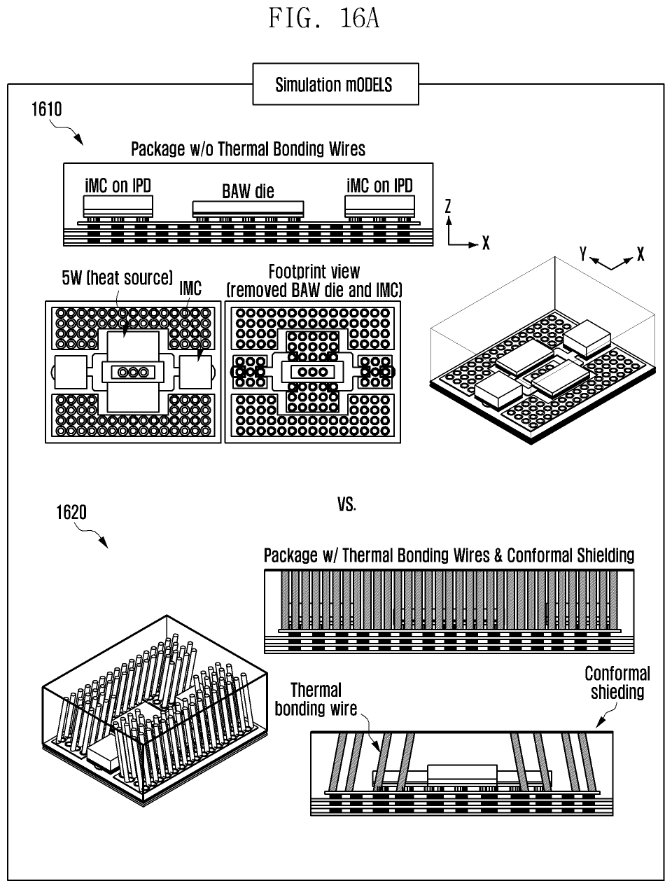

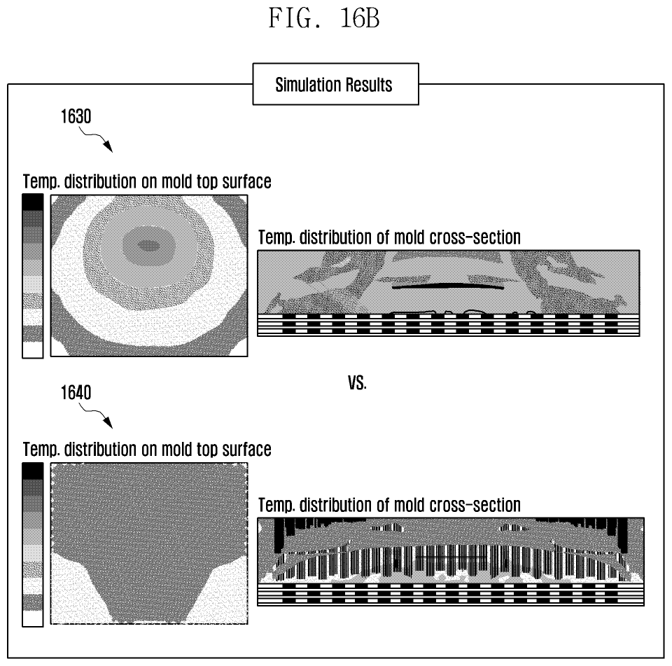

FIG. 16A illustrates high-power acoustic wave filter packages designed to verify an effect of thermal bonding wires according to an embodiment of the disclosure.

Referring to FIG. 16A, model 1610 and model 1620 are assumed to have the same configuration except for a thermal bonding wire. Model 1610 has no thermal bonding wire inserted, and model 1620 has thermal bonding wires inserted.

FIG. 16B illustrates a thermal analysis result according to whether a thermal bonding wire is applied according to an embodiment of the disclosure.

FIG. 16B illustrates a thermal analysis results of model 1610 and model 1620 of FIG. 16A.

Referring to FIG. 16B, 1630 indicates the thermal analysis result of model 1610 having no thermal bonding wire inserted, and 1640 indicates the thermal analysis result of model 1620 having the thermal bonding wires inserted. A simulation shows that temperature rises higher in a case where no thermal bonding wire is inserted than in a case where the thermal bonding wires are inserted. Therefore, a package may be configured by inserting a thermal boding wire, thereby resolving heat generation in the package.

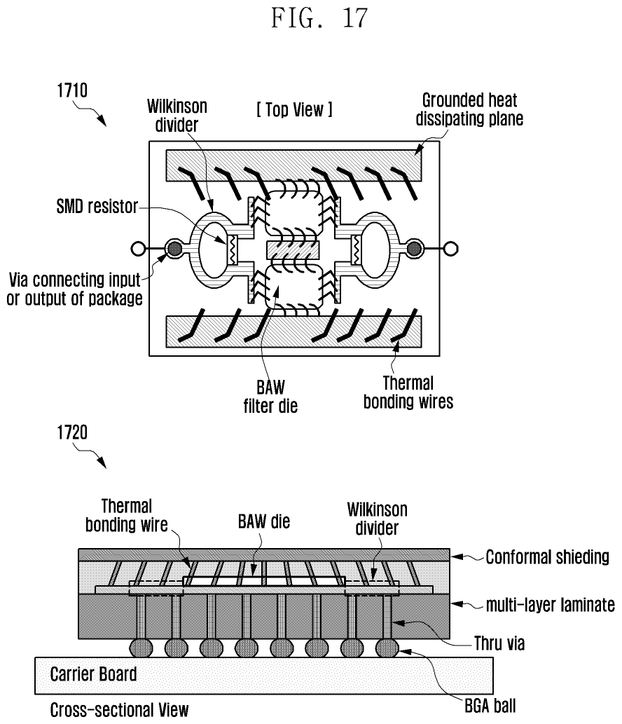

Hereinafter, specific examples of a high-power acoustic wave filter package according to various embodiments of the disclosure will be described with reference to FIGS. 17 to 22.

In the high-power acoustic wave filter package according to various embodiments of the disclosure, grounded heat dissipating planes may be disposed on the upper surface of a top metal layer of the package, and may be configured in various shapes. The grounded heat dissipating planes may be coupled/connected to other metal layers through vias.

In the high-power acoustic wave filter package according to various embodiments of the disclosure, thermal bonding wires may be connected to bonding pads formed on the grounded heat dissipating planes. For example, thick bonding wires may be used as the thermal bonding wires. An array of the thermal bonding wires may form an electrical connection between the grounded heat dissipating planes and a conformal shielding.

In the high-power acoustic wave filter package according to various embodiments of the disclosure, a PDCS may have various structures. For example, the PDCS may be any circuit having a combination of lumped inductors and capacitors. Alternatively, the PDCS may be designed using metal strips of various shapes and lumped inductors and capacitors. Alternatively, the PDCS may be fabricated on an integrated passive device (IPD). For example, the PDCS may be designed on the top metal layer of the package. Alternatively, the PDCS may be designed on an inner metal layer of the package. Alternatively, the PDCS may be mounted on the bottom metal lay of the package like a flip chip.

In the high-power acoustic wave filter package according to various embodiments of the disclosure, an IMC may have various structures. For example, the IMC may be a combination of metal strips or open/short stubs of various shapes. Alternatively, the IMC may be configured using lumped inductors (L) or capacitors (C). Alternatively, the IMC may be designed using open/short stubs of various shapes and lumped inductors and capacitors. Alternatively, the IMC may be configured using an IPD. For example, the IMC may be designed on the top metal layer of the package. Alternatively, the IMC may be designed in an inner metal layer of the package. Alternatively, the IMC may be mounted on the bottom metal layer of the package like a flip chip.

FIG. 17 illustrates a high-power acoustic wave filter package designed using a Wilkinson divider according to an embodiment of the disclosure.

Referring to FIG. 17, 1710 shows a top view of the high-power acoustic wave filter package designed using the Wilkinson divider, and 1720 shows a cross-sectional view of the high-power acoustic wave filter package designed using the Wilkinson divider.

The Wilkinson divider may be used as an IMC and a PDCS. For example, the Wilkinson divider may serve both as the IMC and as the PDCS. The Wilkinson divider and a grounded heat dissipating plane may be formed on the top metal layer of the package. The Wilkinson divider may be connected to BAW filter dies disposed/connected in parallel. The Wilkinson divider may be connected to the input or output of the package through a via.

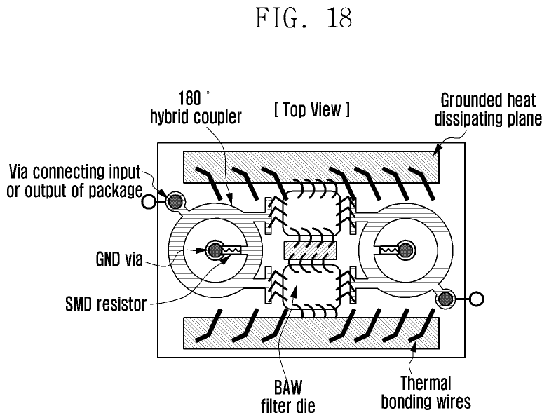

FIG. 18 illustrates a high-power acoustic wave filter package designed using a 180-degree hybrid coupler according to an embodiment of the disclosure.

Referring to FIG. 18, the 180-degree hybrid coupler may be used as a PDCS and an IMC. The 180-degree hybrid coupler used for impedance matching with the PDCS may be disposed on the top metal layer of the package. The 180-degree hybrid coupler may be connected to BAW filter dies disposed/connected in parallel. The 180-degree hybrid coupler may be connected to the input or output of the package through a via.

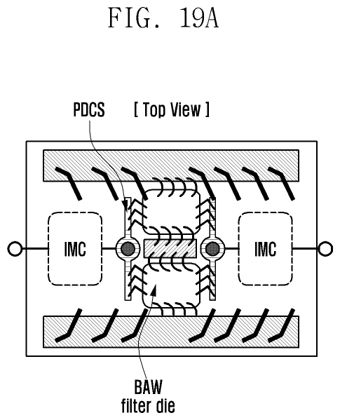

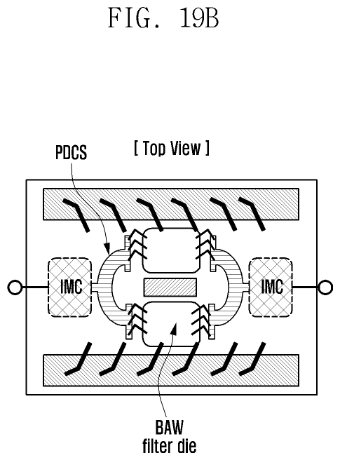

FIGS. 19A and 19B illustrates a high-power acoustic wave filter package according to an embodiment of the disclosure.

Referring to FIG. 19A, an IMC may be constructed in an inner metal layer of the package. When a PDCS and the IMC are disposed in different layers, the PDCS and the IMC may be connected through a via. Alternatively, referring to FIG. 19B, the IMC may be constructed on the top metal layer of the package. When the PDCS and the IMC are disposed in the same layer, the PDCS and the IMC may be connected to each other through a wire of the layer.

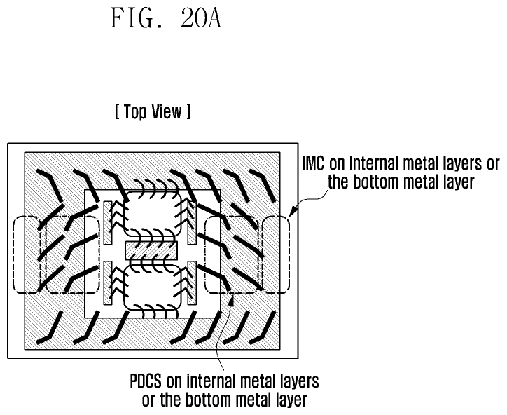

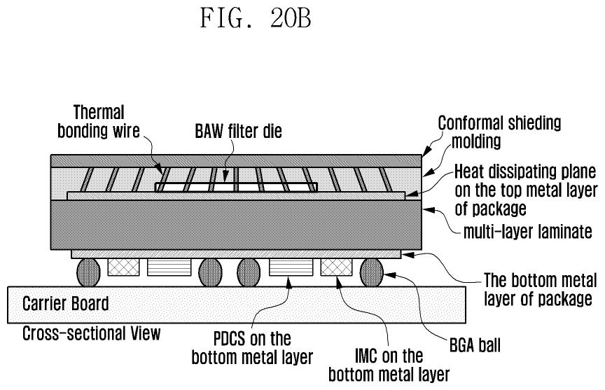

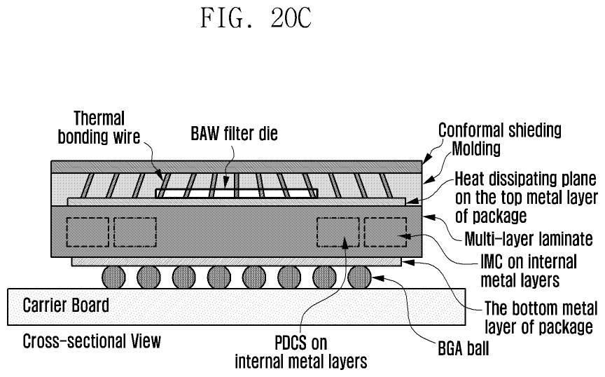

FIGS. 20A, 20B, and 20C illustrate a high-power acoustic wave filter package structure according to an embodiment of the disclosure.

FIG. 20A illustrates a top view of the filter package structure according to an embodiment of the disclosure, and FIGS. 20B and 20C illustrate cross-sectional views of the filter package structure according to an embodiment of the disclosure.

Referring to FIG. 20A, a heat dissipating plane and an acoustic wave filter die may be disposed on the top metal layer. In addition, a PDCS and an IMC may be disposed in an internal metal layer or on the bottom surface of the package. For example, as illustrated in FIG. 20B, both the PDCS and the IMC may be disposed on the bottom surface of the package. The PDCS disposed on the bottom surface of the package and the acoustic wave filter die disposed on the top metal layer may be connected through a via. In another example, as illustrated in FIG. 20C, both the PDCS and the IMC may be disposed in internal metal layers. The PDCS disposed in the internal metal layer and the acoustic wave filter die disposed on the top metal layer may be connected through a via. When the PDCS and the IMC are disposed in the internal metal layers, the PDCS and the IMC may be disposed in the same layer or in different layers. Alternatively, although not shown in FIGS. 20A, 20B, and 20C, the PDCS may be disposed in an internal metal layer, and the IMC may be disposed on the bottom surface of the package. Alternatively, the PDCS may be disposed on the bottom surface of the package, and the IMC may be disposed in an internal metal layer.

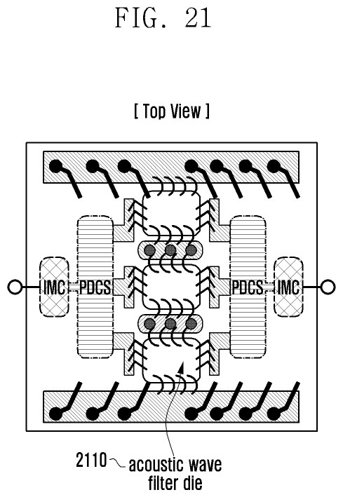

FIG. 21 illustrates a high-power acoustic wave filter package according to an embodiment of the disclosure.

For convenience of explanation, the embodiment is described with reference to an example in which two acoustic wave filter dies are included in one package, but three or more acoustic wave filter dies 2110 may be included in one package. The three or more acoustic wave filter dies may be disposed in parallel.

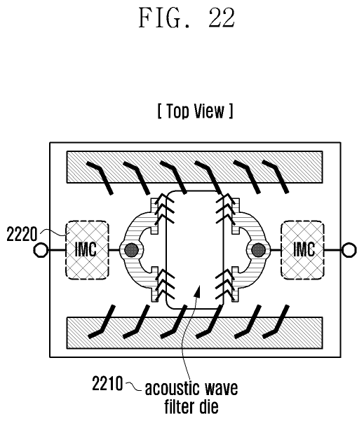

FIG. 22 illustrates a high-power acoustic wave filter package according to an embodiment of the disclosure.

Referring to FIG. 22, a plurality of acoustic wave filters may be fabricated on a single die 2210. The plurality of acoustic wave filters may be fabricated on the single die and packaged using wire bonding or a flip chip. For example, an IMC 2220 may be designed in an inner metal layer of the package. As described above, the IMC may have various shapes/structures. When a PDCS and the IMC are disposed in different layers, the PDCS and the IMC may be connected through a via.

The foregoing high-power acoustic wave filter packages of the disclosure may be included in an electronic device that transmits or receives a signal at various frequencies. For example, the electronic device may be a base station. Alternatively, the electronic device may be a wireless device that performs functions equivalent to those of a base station, a wireless device (e.g., a TRP) connected to a base station, a UE, or other communication devices used for wireless communication.

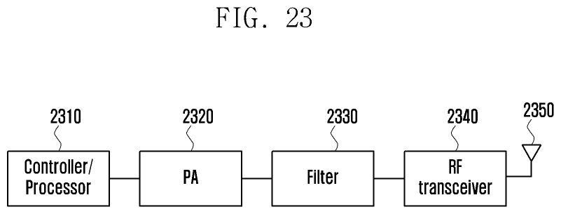

FIG. 23 illustrates an electronic device according to an embodiment of the disclosure.

Referring to FIG. 23, the electronic device may include a controller/processor 2310, a PA 2320, a filter 2330, an RF transceiver 2340, and an antenna 2350.

Although FIG. 23 shows one antenna and one RF transceiver, which is only for illustration, the antenna of the electronic device may include a plurality of antennas, and the RF transceiver of the electronic device may include a plurality of RF transceivers.

The controller/processor 2310 may include one or more processors or other processing devices that control the overall operation of the electronic device. For example, the controller/processor 2310 may control reception of am uplink channel signal and transmission of a downlink channel signal by the RF transceiver 2340, an RX processing circuit (not shown), and a TX processing circuit (not shown) according to a well-known principle. The controller/processor 2310 may also support an additional function, such as an advanced wireless communication function. Any of a variety of other functions may be supported by the controller/processor 2310 in the electronic device. In some embodiments of the disclosure, the controller/processor 2310 includes at least one microprocessor or microcontroller.

The controller/processor 2310 may also execute a memory-resident program, such as an operating system (OS), and other processes. The controller/processor 2310 may move data into and out of memory as required by an executed process. For example, the controller/processor 2310 may move data into and out of memory depending on a process being executed.

The controller/processor 2310 may also manage/control power of the electronic device, or may control components related to power management/control of the electronic device. For example, the controller/processor 2310 may control a power supply circuit to provide a voltage for the operating range of the PA 2320 to the PA 2320.

The PA 2320 may amplify and output a signal entering an input terminal of the PA. For example, the PA 2320 may provide an output signal of up to M Watt.

The filter 2330 may be used to increase the frequency selectivity of a signal having a specific frequency on a transmission/reception path of the electronic device. The filter 2330 may have a rated capacity for allowing M watt, which is an output power of the PA 2320. For example, the filter 2330 may be configured as a filter device. For example, filter 2330 may include a plurality of acoustic wave filters, power dividing and combining components, and heat dissipating components connected in parallel. In addition, the filter 2330 may further include impedance matching circuits.

The RF transceiver 2340 may receive an RF signal transmitted by a UE in a wireless network from the antenna 2350, and may transmit an RF signal through the antenna 2350.

The antenna 2350 may be configured as an antenna array in which a plurality of antennas are gathered. The antenna array may be configured in various forms, such as a linear array and a planar array. The antenna array may be referred to as a massive antenna array.

Although FIG. 23 illustrates an example of an electronic device, various modifications may be made to FIG. 23. For example, the electronic device may include any number of each of the components illustrated in FIG. 23. In addition, various components of FIG. 23 may be combined, further subdivided, or omitted, and additional components may be added as specifically needed.

The methods according to various embodiments described in the claims or the specification of the disclosure may be implemented by hardware, software, or a combination of hardware and software.

When the methods are implemented by software, a computer-readable storage medium for storing one or more programs (software modules) may be provided. The one or more programs stored in the computer-readable storage medium may be configured for execution by one or more processors within the electronic device. The at least one program may include instructions that cause the electronic device to perform the methods according to various embodiments of the disclosure as defined by the appended claims and/or disclosed herein.

The programs (software modules or software) may be stored in non-volatile memories including random access memory and flash memory, read only memory (ROM), electrically erasable programmable read only memory (EEPROM), magnetic disc storage device, compact disc-ROM (CD-ROM), digital versatile discs (DVDs), or other type optical storage devices, or a magnetic cassette. Alternatively, any combination of some or all of them may form memory in which the program is stored. Further, a plurality of such memories may be included in the electronic device.

In addition, the programs may be stored in an attachable storage device which may access the electronic device through communication networks, such as the Internet, Intranet, local area network (LAN), wide LAN (WLAN), and storage area network (SAN) or a combination thereof. Such a storage device may access the electronic device implementing embodiments of the disclosure via an external port. Further, a separate storage device on the communication network may access the electronic device implementing embodiments of the disclosure.

In the above-described detailed embodiments of the disclosure, an element included in the disclosure is expressed in the singular or the plural according to presented detailed embodiments. However, the singular form or plural form is selected appropriately to the presented situation for the convenience of description, and the disclosure is not limited by elements expressed in the singular or the plural. Therefore, either an element expressed in the plural may also include a single element or an element expressed in the singular may also include multiple elements.

The flowchart illustrates an method that may be implemented according to the principles of the disclosure, and various changes may be made to the method illustrated in the flowchart herein. For example, although illustrated as a series of steps, the various steps in each drawing may overlap, occur in parallel, occur in a different order, or occur multiple times. In other examples, steps may be omitted or replaced with other steps. The values described above are only examples, and it is entirely possible for other values to be applied.

The embodiments of the disclosure described and shown in the specification and the drawings have been presented to easily explain the technical contents of the disclosure and help understanding of the disclosure, and are not intended to limit the scope of the disclosure. For example, it will be apparent to those skilled in the art that other modifications and changes may be made thereto based on the technical idea of the disclosure. Further, the above respective embodiments may be employed in combination, as necessary.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A filter package comprising:
a plurality of metal layers stacked in a vertical direction;
a plurality of acoustic wave filters connected in parallel, the plurality of acoustic wave filters being located at one of the plurality of metal layers;
power dividing and combining components connected with the plurality of acoustic wave filters; and
heat dissipating components.

2. The filter package of claim 1,
wherein the heat dissipating components are located at a top metal layer among the plurality of metal layers, and
wherein the heat dissipating components at the top metal layer are connected to other metal layers through vias.

3. The filter package of claim 2,
wherein the filter package further includes a conformal shield formed on an upper surface of the filter package,
wherein the heat dissipation components at the top metal layer include thermal bonding wires and bonding pads for the thermal bonding wires, and
wherein the thermal bonding wires connect the bonding pads and the conformal shield vertically.

4. The filter package of claim 3, wherein the thermal bonding wires are connected symmetrically up and down or left and right based on a horizontal or vertical center line of the filter package.

5. The filter package of claim 4, further comprising:
a heat sink on the conformal shield.

6. The filter package of claim 1, wherein the power dividing and combining components comprise one of a Wilkinson power divider or a 180 degree hybrid coupler.

7. The filter package of claim 1,
wherein the power dividing and combining components include a first power dividing and combining component and a second power dividing and combining component,
wherein the first power dividing and combining component is a power divider dividing an input power of the filter package and delivering divided powers to inputs of the plurality of acoustic wave filters, and
wherein the second power dividing and combining component is a power combiner combining output powers from the plurality of acoustic wave filters.

8. The filter package of claim 7, further comprising:
a first impedance matching circuit located between an input of the filter package and the first power dividing and combining component; and
a second impedance matching circuit located between an output of the filter package and the second power dividing and combining component.

9. The filter package of claim 8,
wherein the plurality of acoustic wave filters and the heat dissipating components are located at a top metal layer among the plurality of metal layers, and
wherein the first power dividing and combining component, the second power dividing and combining component, the first impedance matching circuit, and the second impedance matching circuit are located an inner metal layer or a bottom side of the filter package.

10. The filter package of claim 1, wherein the plurality of acoustic wave filters comprises one of surface acoustic wave (SAW) filters and a bulk acoustic wave (BAW) filters.

11. The filter package of claim 1, wherein the plurality of acoustic wave filters are fabricated in a single die.

12. An electric device in a wireless communication system, the electric device comprising:
antennas; and
a filter device operably connected to at least one of the antennas,
wherein the filter device includes a plurality of acoustic wave filters connected in parallel, power dividing and combining components connected with the plurality of acoustic wave filters, and heat dissipating components.

13. The electric device of claim 12,
wherein the power dividing and combining components include a first power dividing and combining component corresponding to a power divider and a second power dividing and combining component corresponding to a power combiner, and
wherein the filter device further includes a first impedance matching circuit connected to the first power dividing and combining component and a second impedance matching circuit connected to the second power dividing and combining component.

14. The electric device of claim 13,
wherein the filter device further includes a heat sink,
wherein the heat dissipation components include thermal bonding wires and bonding pads for the thermal bonding wires, and
wherein the power dividing and combining components comprise one of a Wilkinson power divider or a 180 degree hybrid coupler.

15. The electric device of claim 12, wherein the plurality of acoustic wave filters comprises one of surface acoustic wave (SAW) filters and a bulk acoustic wave (BAW) filters.

16. The electric device of claim 14, wherein the thermal bonding wires are connected symmetrically up and down or left and right based on a horizontal or vertical center line of a filter package.

17. The electric device of claim 12, wherein the plurality of acoustic wave filters are fabricated in a single die.

18. The electric device of claim 12, wherein the heat dissipating components are located at a top metal layer among a plurality of metal layers.

19. The electric device of claim 18, wherein the heat dissipating components at the top metal layer are connected to other metal layers through vias.

20. The electric device of claim 16, wherein the first power dividing and combining component, the second power dividing and combining component, the first impedance matching circuit, and the second impedance matching circuit are located an inner metal layer or a bottom side of the filter package.
